(19) United States
(12) Patent Application Publication
(10) Pub. No.: US 2007/0001295 A1
(43) Pub. Date: Jan. 4, 2007

(54) Semiconductor device and fabrication method thereof

(76) Inventors: Jung-Chan Cho, Cheonan-si (KR); Byung-Man Kim, Cheonan-si (KR); Yong-Hyun Kim, Suwon-si (KR)

Correspondence Address: HARNESS, DICKEY & PIERCE, P.L.C., P.O. BOX 8910, RESTON, VA, 20195, US

(21) Appl. No.: 11/454,905

(22) Filed: Jun. 19, 2006

(30) Foreign Application Priority Data
Jun. 17, 2005 (KR) 10-2005-0052485

(51) Int. Cl. H01L 23/34

(52) U.S. Cl. 257/723

(57) ABSTRACT

A semiconductor device and a method of fabricating the same may be provided. The semiconductor device may include an insulation material as a base frame of a PCB, including an opening penetrating the insulation material with sidewalls plated with a gold (Au) layer. The semiconductor device may further include a printed circuit board for use in a module, having a pad whose surface may be coated with an organic solderability preservative (OSP) and an opening whose sidewalls may be plated with a nickel (Ni) layer and a gold (Au) layer, and a semiconductor device mounted on the PCB via the pad. During a temperature cycling reliability test on the semiconductor device, no defects, for example, cracks may form inside the opening.

### PRIORITY STATEMENT

This application claims priority under 35 USC § 119 to Korean Patent Application No. 10-2005-0052485, filed on Jun. 17, 2005, in the Korean Intellectual Property Office (KIPO), the entire contents of which are incorporated herein by reference.

### BACKGROUND

1. Field

Example embodiments of the present invention relate to a semiconductor device, for example, a semiconductor memory module which reduces cracks inside openings of a printed circuit board during a thermal cycling reliability test, and a method of fabricating the same.

2. Description of the Related Art

Prior to releasing semiconductor devices, for example, memory modules, into the market, manufacturers test whether the semiconductor devices may operate normally even under the worst usage conditions, which is called a reliability test.

A temperature cycle test may be one type of reliability test. The temperature cycle test may check whether semiconductor memory modules operate normally, even under the worst temperature conditions. For example, semiconductor modules may be held at about −25° C. for about 10 minutes and may be transferred at about 125° C. for about 10 minutes, and this operation may be repeated about 600 to about 1,000 times.

FIG. 1 is a conventional semiconductor device, for example, a semiconductor memory module.

Referring to FIG. 1, the semiconductor memory module 20 may include a printed circuit board (PCB) 10 on which circuit patterns (not shown) may be formed, a plurality of semiconductor devices 16 that may perform the same function, for example, semiconductor memory packages, mounted on the PCB 10 and a connecting terminal 12 that may be formed at one edge of the PCB 10 for electrically connecting the semiconductor memory module 20 to an external motherboard.

FIG. 2 illustrates pads and openings on the PCB of the semiconductor memory module 20 shown in FIG. 1.

The PCB 10 may include a plurality of pads 18 with which solder balls of semiconductor devices may be connected and a plurality of openings 14 which may connect upper and lower circuit patterns of the PCB 10.

FIG. 3 is a conventional pad formed on a PCB. FIG. 4 is a conventional opening. Like reference numerals denote like elements in FIGS. 1 through 4.

As shown, a circuit pattern 30, for example, a pad 18 and an opening 14, may be a metal pattern formed of a copper (Cu)-based material. However, when the metal pattern is exposed to air, copper (Cu) may react with oxygen in the air to form compounds of oxygen and/or copper (Cu) (oxides). When solder balls of semiconductor devices are attached to the pad 18, these oxide compounds may decrease adhesion.

An organic solderability preservative (OSP) 24, which may be a water-soluble antioxidant, may be coated on the copper (Cu) based circuit pattern 30 to reduce surface oxidization of the pad 18. As shown in FIG. 4, the OSP 24 may be coated on the copper (Cu) based circuit pattern 30, which may be formed over an opening 14, to reduce oxidization.

The OSP 24 may not be coated on metals, for example, gold (Au) and/or the like, but may be selectively coated on copper (Cu) and/or the like. The OSP 24 may be a water-soluble antioxidant having adhesion to copper (Cu). The OSP 24 may continue to function as an antioxidant for copper (Cu) at temperatures of up to about 250° C. A substrate 26 may be based on an insulating material, e.g., flame retardant (FR)-4 resin and/or the like, and a photo solder resist (PSR) 22 may be formed over a circuit pattern 30.

FIGS. 5 and 6 illustrate cracks formed inside the opening during a temperature cycling reliability test on the conventional semiconductor memory module.

The above-described OSP may be removed during the fabrication of the semiconductor memory module. A plurality of semiconductor devices may be arranged on the PCB and electrically connected with the PCB by solder 28, thereby finishing the fabrication of the semiconductor memory module. However, when the temperature cycling reliability test is performed on the semiconductor memory module, a crack 32 may form in the solder 28 filling an opening 14 of the PCB, or cracks 34 may form in copper (Cu)-based circuit patterns 30 formed over the sidewalls of the opening 14. Cracks 32 and 34 may reduce the reliability of the semiconductor memory module.

Copper (Cu) of the circuit patterns 30, the FR4 resin of the substrate 26, and the solder 28 which fills the opening 14 may all have different coefficients of thermal expansion (CTE). When these materials are exposed to an abrupt temperature change, they may expand and contract differently, thereby generating stress. As a result, the cracks 32 and 34 may be more likely to form in the solder 28 and the copper (Cu)-based circuit patterns 30.

The cracks may decrease the lifetime and electrical performance of the semiconductor memory modules.

### SUMMARY

Example embodiments of the present invention may provide a semiconductor device which avoids cracking during a temperature cycling reliability test.

Example embodiments of the present invention may also provide a method of fabricating a semiconductor device which avoids cracking during a temperature cycling reliability test.

According to an example embodiment of the present invention, there may be provided a semiconductor device, comprising an insulation material as a base frame of a PCB, including an opening penetrating the insulation material with sidewalls plated with a gold (Au) layer.

The semiconductor device may further include a printed circuit board for use in a module, having a pad whose surface may be coated with an organic solderability preservative (OSP), and a semiconductor device mounted on the PCB via the pad.

The sidewalls of the opening may be plated sequentially with a nickel (Ni) layer and a gold (Au) layer. For example, the printed circuit board may include a connecting terminal to make an electrical connection with a motherboard. The semiconductor device may be a semiconductor memory module.

According to another example embodiment of the present invention, there may be provided a method of fabricating a semiconductor device. The method may include preparing a PCB including a pad whose surface is coated with an OSP and an insulation material including an opening that penetrates the insulation material with sidewalls plated with a gold (Au) layer, performing a flux process to remove the coated OSP from the pad surface, and mounting a semiconductor device on the PCB.

Preparing the PCB may include laminating copper (Cu) foil on both sides of a substrate formed of an insulation material, performing a drilling process to form the opening in the PCB; forming copper (Cu) plating layers on the PCB; forming a plurality of first dry films for patterning the copper (Cu) plating layers and the copper (Cu) foils, etching the copper (Cu) plating layer and the copper (Cu) foil using the dry films to form a plurality of circuit patterns, removing the first dry films, forming a plurality of PSR (photo solder resist) layers over the circuit patterns except for the pad and the opening, forming a plurality of second dry films exposing the opening, forming a gold (Au) plating layer on the sidewalls of the exposed opening, removing the second dry films, and coating an OSP on the pad.

A nickel (Ni) layer of about 2 μm to about 5 μm thick may be further formed on the copper (Cu) plating layers on the sidewalls of the opening.

According to example embodiments of the present invention, the pad surface of the PCB may be coated with the OSP, and the nickel (Ni) layer and the gold (Au) plating layers may be formed on the sidewalls of the opening. As a result, it may be possible to avoid cracking during a temperature cycling reliability test.

### BRIEF DESCRIPTION OF THE DRAWINGS

The above and other features and advantages of example embodiments of the present invention will become more apparent by describing in detail example embodiments thereof with reference to the attached drawings in which:

FIG. 1 is a conventional semiconductor memory module as an example of a semiconductor device;

FIG. 2 is a pad and an opening on a conventional PCB of the conventional semiconductor memory module illustrated in FIG. 1;

FIG. 3 is the pad of the conventional PCB illustrated in FIG. 2;

FIG. 4 is the opening of the conventional PCB illustrated in FIG. 2;

FIGS. 5 and 6 illustrate cracks formed inside the opening during a temperature cycling reliability test on the conventional semiconductor memory module;

FIG. 7 is a semiconductor memory module, according to an example embodiment of the present invention;

FIG. 8A is a pad and an opening on a PCB of the semiconductor memory module illustrated in FIG. 7, according to an example embodiment of the present invention;

FIG. 8B is a semiconductor device of the semiconductor memory module shown in FIG. 7;

FIG. 9 is a pad on a PCB of a semiconductor device, according to another example embodiment of the present invention;

FIG. 10 is an opening on a PCB of a semiconductor device, according to another example embodiment of the present invention;

FIGS. 11 through 19 illustrate a PCB used in a semiconductor device, according to another example embodiment of the present invention, for illustrating a method of fabricating the same; and

FIG. 20 is a flowchart for illustrating a method of fabricating a semiconductor device, according to another example embodiment of the present invention.

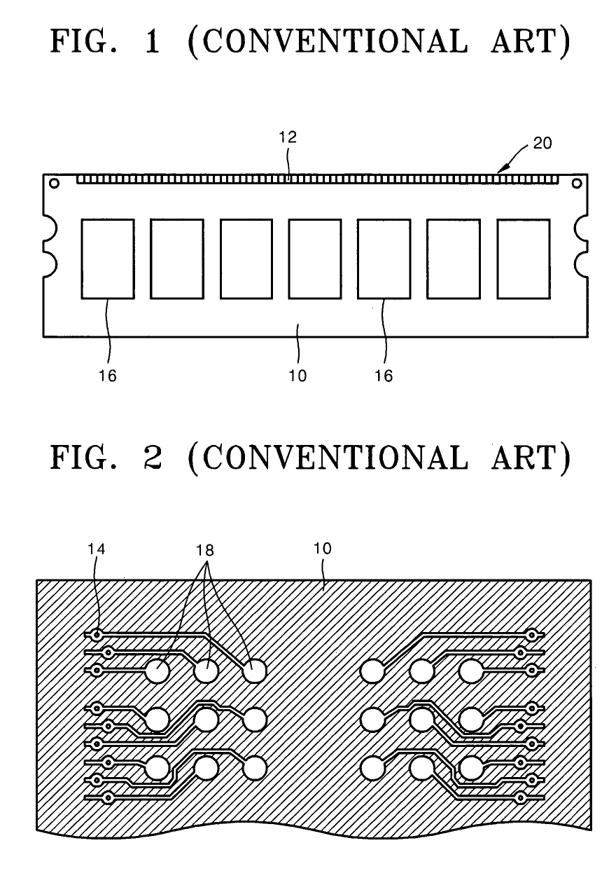

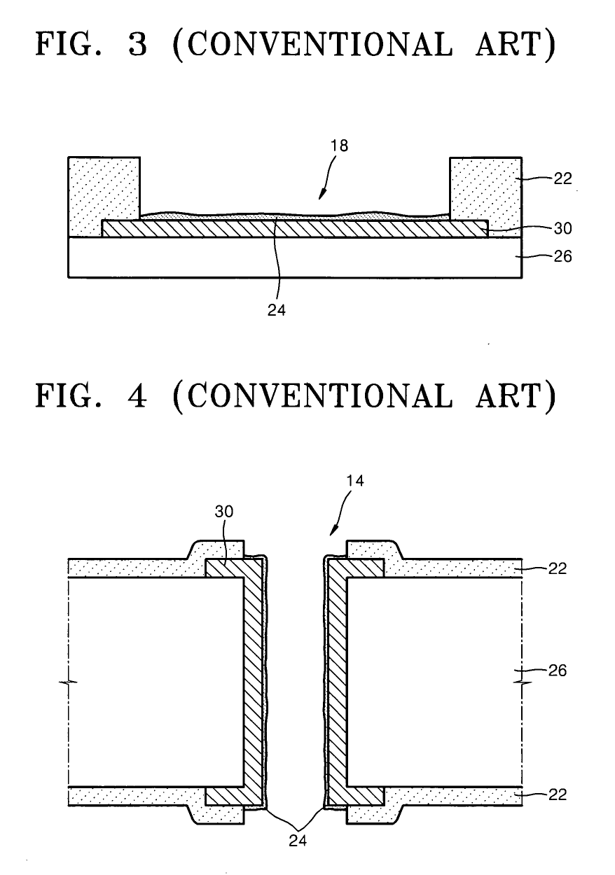

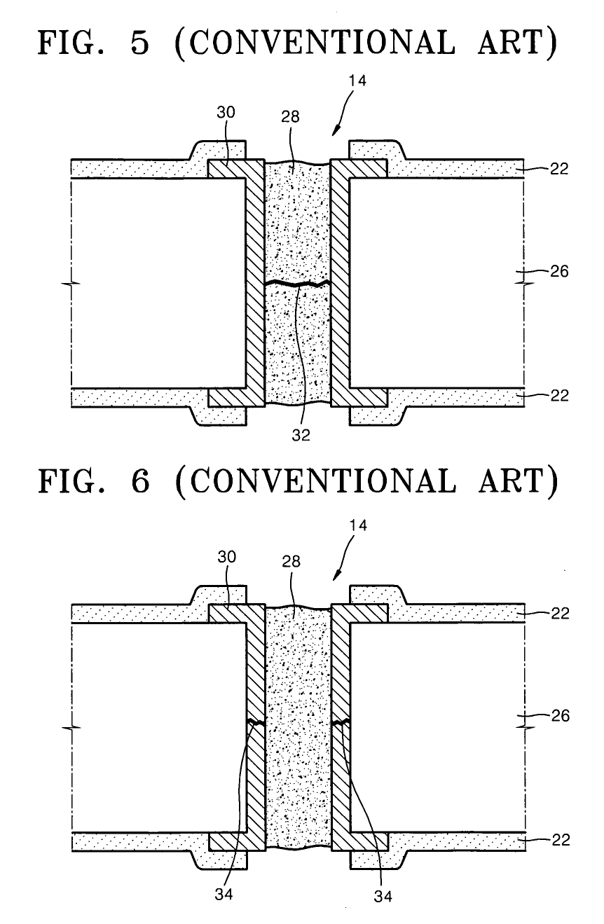

### DETAILED DESCRIPTION OF THE EXAMPLE EMBODIMENTS

Various example embodiments of the present invention will now be described more fully with reference to the accompanying drawings, in which some example embodiments of the present invention are shown. Example embodiments of the present invention are not limited to the example embodiments set forth herein; rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of the example embodiments of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 7 is a semiconductor device, according to an example embodiment of the present invention.

The semiconductor device 100 may be a semiconductor memory module, and may include: a PCB 110 on which a pad and an opening may be formed; and a plurality of semiconductor devices 120 which may be mounted on the PCB 110. The surface of the pad may be coated with an OSP, and the sidewalls of an opening may be plated with gold (Au). For example, a connecting terminal 130 may be formed at one edge of the PCB 110 for electrical connection to a motherboard. For example, semiconductor devices 120 may be selected from a semiconductor package group consisting of a ball grid array (BGA) packages, chip scale packages (CSP) and/or wafer level packages (WLP). Also, the plurality of semiconductor devices 120 may perform the same functions.

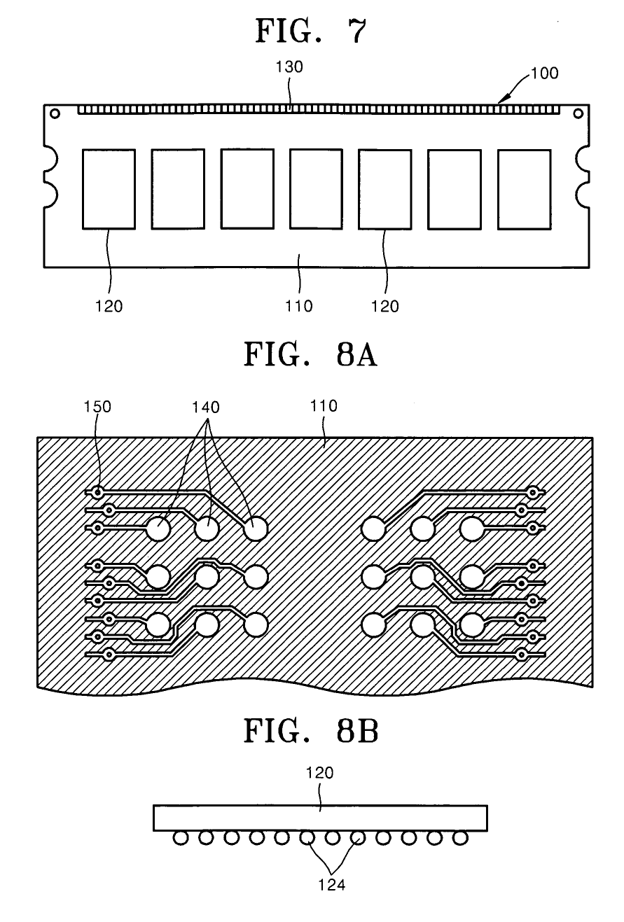

FIG. 8A is a pad and an opening on a PCB of the semiconductor memory module illustrated in FIG. 7.

Referring to FIG. 8A, a PCB 110 may include: a plurality of pads 140 with which solder balls of semiconductor devices may be connected; and a plurality of openings 150 which may connect upper and lower circuit patterns of the PCB 110.

FIG. 8B is a semiconductor device used in the semiconductor device illustrated in FIG. 7. The semiconductor device 120 may use a BGA package, and solder balls 124 on a body may be connected to a pad of the PCB to electrically connect the BGA package 120 (e.g., the semiconductor device) to the PCB. It should be noted that the semiconductor device 120 may be one example of the semiconductor device. Other various modifications of the semiconductor device may be possible. For instance, instead of using solder balls, semiconductor chips may be installed on the PCB, which may be subsequently connected to the semiconductor device by wires.

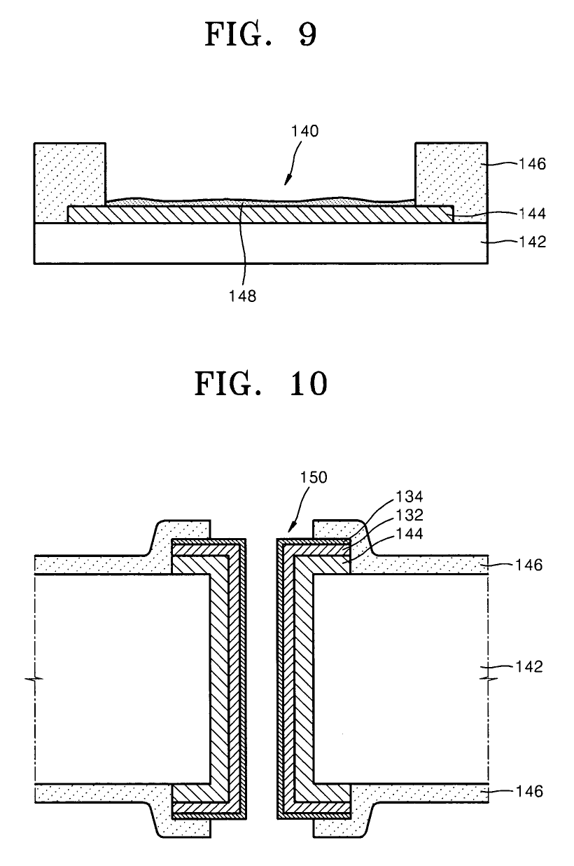

FIG. 9 is a pad of a PCB in a semiconductor device, according to another example embodiment of the present invention.

The surface of the pad 140 of the PCB, which is a base frame, may be coated with an OSP layer 148 to reduce oxidization of a circuit pattern 144, which may be formed of copper (Cu). The copper (Cu)-based circuit pattern 144 may be formed on a substrate 142, formed of an insulating material. A plurality of PSR layers 146 may be formed on portions of the circuit pattern 144 to reduce short circuits by foreign materials. The substrate 142 may include a material selected from the group including epoxy based resin, bismaleimide triazine (BT) resin, FR4 resin and/or the like.

Generally, once the surface of the pad 140 is coated with the OSP layer 148, the surface of each copper (Cu)-based circuit pattern located over an opening may also be coated with an OSP. However, according to another example embodiment of the present invention, the opening may be formed in a specific structure to reduce cracking during a temperature cycling reliability test. The specific structure of the opening will be described with reference to FIG. 10.

FIG. 10 is an opening of a PCB in a semiconductor device, according to the example embodiment of the present invention, described above.

An opening 150 includes a gold (Au) plating layer 134 formed over the opening 150. For example, a nickel (Ni) layer 132 of about 2 μm to about 5 μm may be formed individually on copper (Cu)-based circuit patterns 144, and then the gold (Au) plating layer 134 of about 0.05 μm to about 0.3 μm may be formed individually on the nickel (Ni) layer 132.

The nickel (Ni) layer 132 may reduce defects, for example, cracks by absorbing stress caused by a CTE difference between the substrate 142 and the copper (Cu)-based circuit patterns 144. The gold (Au) plating layer 134 may serve as a moistening layer, which may help solder adhere to the nickel (Ni) layer 132 when the solder fills the opening 150.

Therefore, the nickel (Ni) layer 132 may relieve stress caused by the CTE difference even when the temperature changes abruptly from between about −25° C. and about 120° C. Hence, it may be possible to reduce cracks in the copper (Cu)-based circuit patterns 144 and the solder filling the opening 150.

FIGS. 11 through 19 illustrate a PCB implemented in a semiconductor device, according to another example embodiment of the present invention.

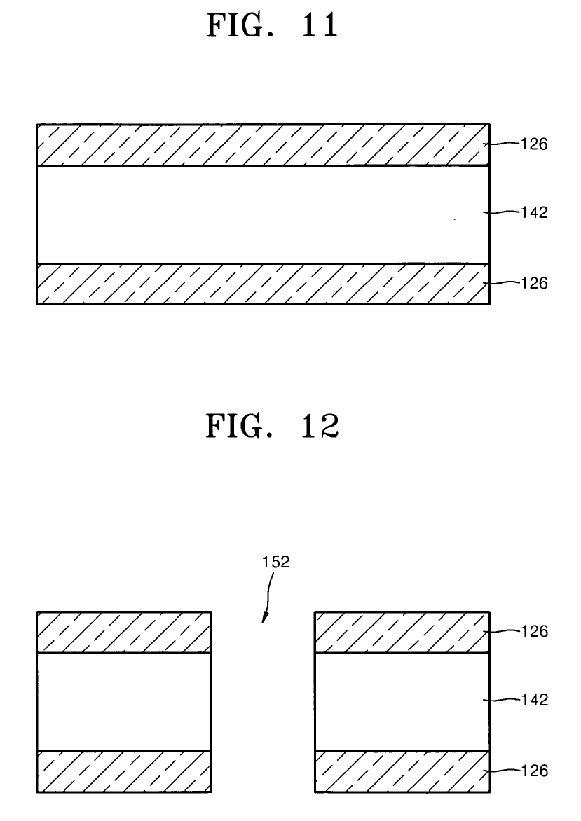

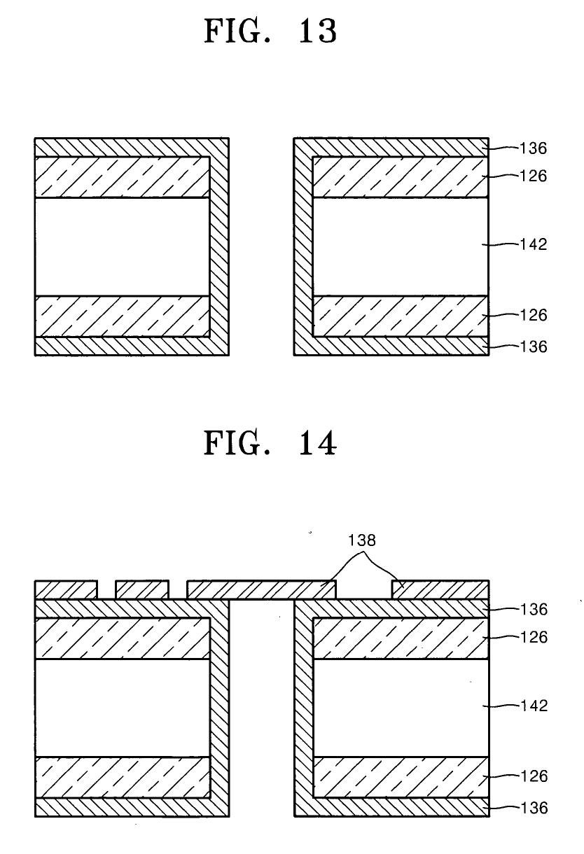

Referring to FIG. 11, a substrate 142 may be formed of an insulating material that may be laminated with copper (Cu) foils 126 on both sides to obtain the PCB. As illustrated in FIG. 12, an opening 152 may be drilled in the PCB. Referring to FIG. 13, a copper (Cu) plating process may be performed on the PCB to form copper (Cu) plating layers 136 on the copper (Cu) foil 126 and the sidewalls of the opening 152, as illustrated in FIG. 12.

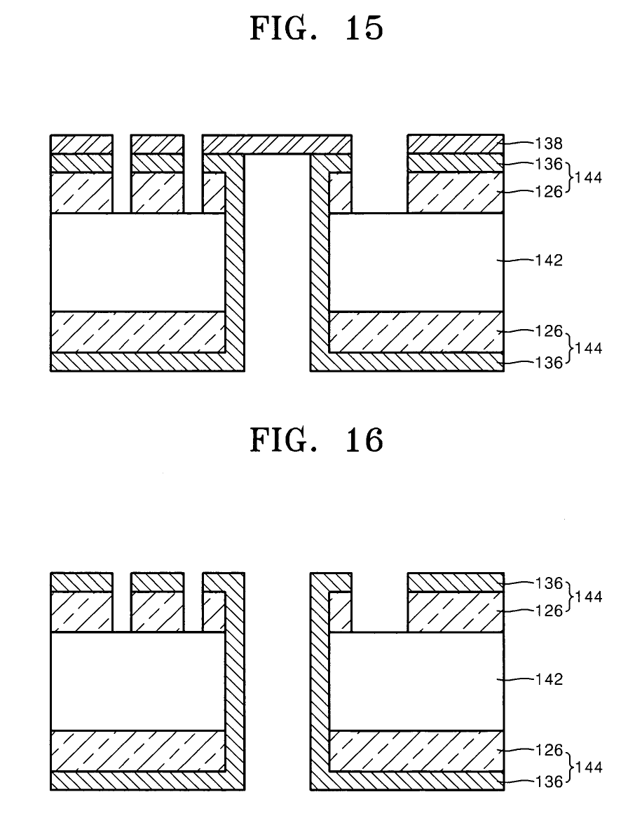

Referring to FIG. 14, a first dry film 138 may be formed on the copper (Cu) plating layers 136 to etch copper (Cu) plating layers 136 and the copper (Cu) foil 126, as illustrated in FIG. 4. The first dry films 138 may be for forming subsequent copper (Cu)-based circuit patterns. Referring to FIG. 15, using the first dry films 138 as an etch mask, the copper (Cu) plating layers 136 and the copper (Cu) foil 126 may be etched to form the copper (Cu)-based circuit patterns 144, and then the first dry films 138 may be removed. FIG. 16 illustrates the removal of the first dry films 138.

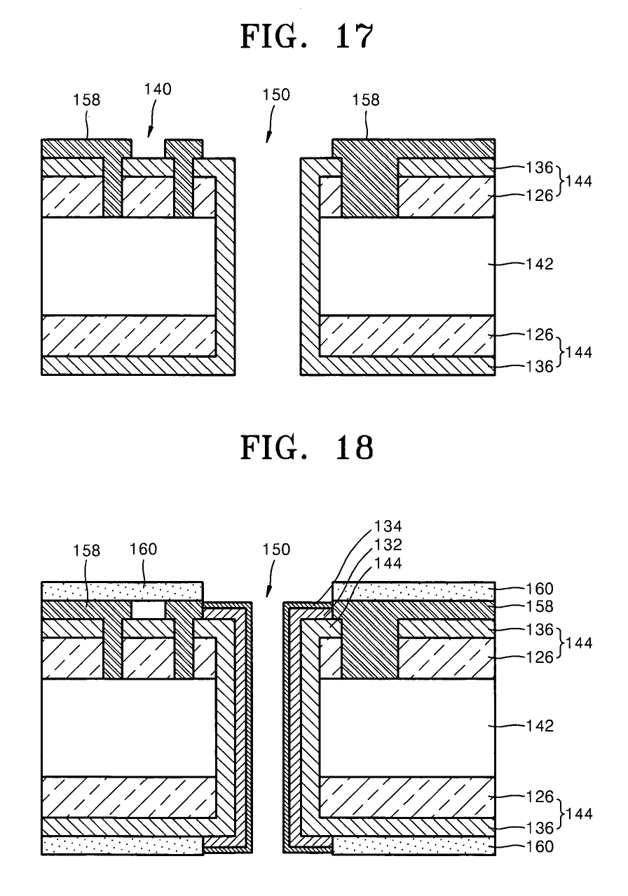

Referring to FIG. 17, a plurality of PSR layers 158 may be formed over the copper (Cu)-based circuit patterns 144, filling the gaps between the circuit patterns 144. However, as illustrated in FIG. 17, the circuit patterns 144 may not be formed over the opening 150 and a pad 140.

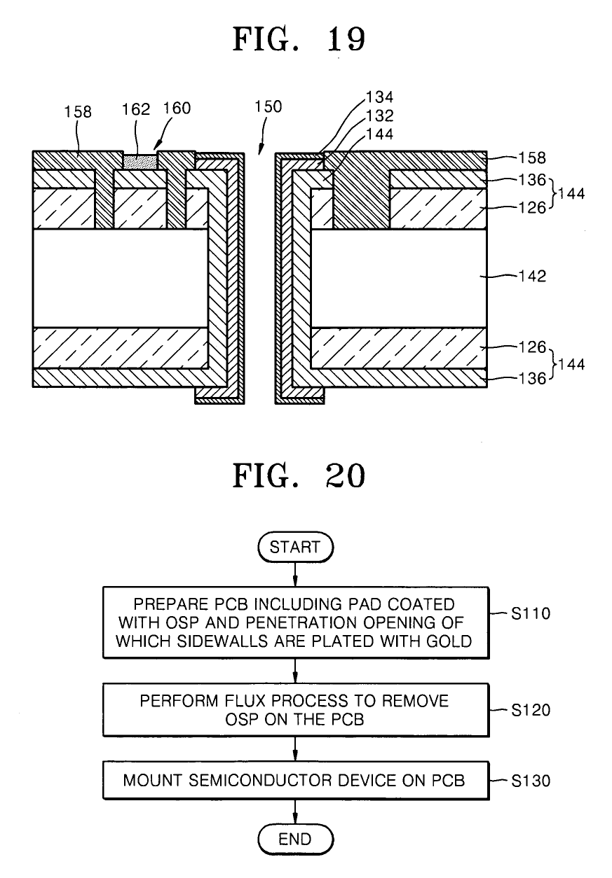

Referring to FIG. 18, a plurality of second dry films 160 may be formed to allow a nickel (Ni) layer 132 and a gold (Au) plating layer 134 to be formed on the sidewalls of the opening 150. The resulting PCB may be electroplated to obtaining the nickel (Ni) layer 132 and the gold (Au) plating layer 134. Referring to FIG. 19, the second dry films 160 may be removed, and an OSP layer 162 may be coated on the exposed pad 160. Because the OSP layer 162 is coated selectively over the copper (Cu) surface (e.g., the copper (Cu) plating layer 136), the OSP layer 162 may not be coated on the gold (Au) plating layer 134.

FIG. 20 is a flowchart illustrating a method of fabricating a semiconductor device, according to another example embodiment of the present invention.

As described in FIGS. 11 through 19, in S110, a PCB may be prepared by coating a pad with an OSP and forming a gold (Au) plating layer over an opening. The PCB has a special structure that may reduce cracks inside the opening during a temperature cycling reliability test.

In S120, a flux cleaning process may be carried out. In detail, flux may be dotted onto the pad, which subsequently passes through an infrared (IR) reflow oven and may then be subjected to a cleaning process to remove the OSP from the pad.

In S130, an installation process may be performed. A plurality of semiconductor devices may be placed on the PCB and an IR reflow oven may be used to melt the solder balls of the semiconductor devices onto the pads of the PCB. For example, the semiconductor devices may be BGA, CSP and/or WLP packages. The semiconductor devices mounted on the PCB perform the same functions, for example, a memory function, and may constitute a semiconductor memory module along with the PCB. The PCB may have a double-sided structure or a multi-layer structure.

A temperature cycling reliability test was performed on the semiconductor memory module having the pad surface of the PCB coated with the OSP and a nickel (Ni) layer and a gold (Au) layer formed over the sidewalls of the opening. The result of the temperature cycling reliability test, according to the example embodiment of the present invention, was compared with the result of the same test on the conventional semiconductor memory module.

In each of the test samples, the pad of the PCB and the copper (Cu)-based circuit patterns formed on the sidewalls of the opening had a thickness of about 25 μm. An abrupt temperature change between about −25° C. and about 125° C. was repeated about 800 times and about 1,000 times at a time interval of about 10 minutes. The formation of cracks inside the opening was investigated.

In the copper (Cu)-based circuit patterns as illustrated in FIG. 4, cracks were discovered in about 6 out of about 11 samples after about 800 abrupt temperature changes. After about 1,000 temperature changes, cracks were discovered in about 3 out of about 5 samples.

In contrast, when the nickel (Ni) layer and the gold (Au) plating layer were additionally formed on the sidewalls of the opening as illustrated in FIG. 10, cracks were not discovered in any of about 9 samples even after about 800 and about 1,000 abrupt temperature changes.

According to an example embodiment of the present invention, a pad surface of a PCB may be coated with an OSP, and a nickel (Ni) layer and a gold (Au) plating layer may be formed on the sidewalls of an opening. As a result, it may be possible to reduce cracking during a temperature cycling reliability test.

The foregoing is illustrative of example embodiments of the present invention and is not to be construed as limiting thereof. Although a few example embodiments of the present invention have been described, those skilled in the art will readily appreciate that many modifications may be possible in the example embodiments without materially departing from the novel teachings and advantages of example embodiments of the present invention. Accordingly, all such modifications are intended to be included within the scope of example embodiments of the present invention as defined in the claims. In the claims, means-plus-function clauses are intended to cover the structures described herein as performing the recited function and not only structural equivalents but also equivalent structures. Therefore, it is to be understood that the foregoing is illustrative of example embodiments of the present invention and is not to be construed as limited to the specific embodiments disclosed, and that modifications to the disclosed embodiments, as well as other embodiments, are intended to be included within the scope of the appended claims. Example embodiments of the present invention are defined by the following claims, with equivalents of the claims to be included therein.

What is claimed is:

1. A semiconductor device, comprising:
an insulation material as a base frame of a PCB, including an opening penetrating the insulation material with sidewalls plated with a gold (Au) layer.

2. The semiconductor device of claim 1, wherein the insulation material is one selected from the group including epoxy based resin, BT (bismaleimide triazine) resin and FR (flame retardant)-4 resin.

3. The semiconductor device of claim 1, wherein the sidewalls of the opening are plated sequentially with a nickel (Ni) layer and the gold (Au) layer.

4. The semiconductor device of claim 3, wherein the nickel (Ni) layer has a thickness of about 2 μm to about 5 μm.

5. The semiconductor device of claim 3, wherein the gold (Au) layer has a thickness of about 0.05 μm to about 0.3 μm.

6. The semiconductor device of claim 1, further comprising:
a printed circuit board (PCB) including a pad formed on the insulation material, wherein a surface of the pad is coated with an organic solderability preservative (OSP); and
at least one semiconductor device mounted on the PCB via the pad.

7. The semiconductor device of claim 6, wherein the semiconductor device is electrically connected to the printed circuit board (PCB) by solder balls.

8. The semiconductor device of claim 6, wherein the at least one semiconductor device is a plurality of semiconductor devices that perform the same function.

9. The semiconductor device of claim 8, wherein the at least one semiconductor device is a semiconductor memory module.

10. The semiconductor device of claim 6, wherein the at least one semiconductor device is one selected from the group including a BGA (ball grid array) package, a CSP (chip scale package) and a WLP (wafer level package).

11. The semiconductor device of claim 6, wherein the printed circuit board includes a connecting terminal to make an electrical connection with a motherboard.

12. A method of fabricating a semiconductor device, comprising:
preparing a PCB including a pad whose surface is coated with an organic solderability preservative (OSP) and an insulation material including an opening penetrating the insulation material with sidewalls plated with a gold (Au) layer;
performing a flux process to remove the coated OSP from the pad surface; and
mounting a semiconductor device on the PCB.

13. The method of claim 12, wherein the preparing of the PCB includes:
laminating copper (Cu) foil on both sides of a substrate formed of an insulation material;
drilling to form the opening in the PCB;
forming copper (Cu) plating layers on the PCB;
forming a plurality of first dry films for patterning the copper (Cu) plating layers and the copper (Cu) foil;
etching the copper (Cu) plating layer and the copper (Cu) foil using the dry films to form a plurality of circuit patterns;
removing the first dry films;
forming a plurality of PSR (photo solder resist) layers over the circuit patterns except for the pad and the opening;
forming a plurality of second dry films exposing the opening;
forming the gold (Au) plating layer on the sidewalls of the exposed opening; and
removing the second dry films and coating an OSP on the pad.

14. The method of claim 12, wherein the insulation material of the PCB is selected from the group including epoxy based resin, BT resin and FR-4 resin.

15. The method of claim 12, wherein the gold (Au) layer is plated to a thickness of about 0.05 μm to about 0.3 μm.

16. The method of claim 12, further comprising:
forming a nickel (Ni) layer of about 2 μm to about 5 μm thick on the copper (Cu) plating layers before performing the gold (Au) plating on the sidewalls of the opening.

17. The method of claim 12, wherein the performing of the flux process to remove the coated OSP from the pad surface includes:
dotting flux onto the pad surface;
passing the PCB where the flux is dotted through an IR (infrared) reflow oven; and
cleaning the PCB.

18. The method of claim 12, wherein the PCB is a multi-layered substrate.

19. The method of claim 12, wherein a plurality of the semiconductor devices are formed and perform identical functions.

20. The method of claim 19, wherein the semiconductor device is a semiconductor memory module.

21. The method of claim 12, wherein the mounting of the semiconductor device on the PCB includes:
placing a plurality of the semiconductor devices each performing a memory function on the PCB; and
passing the PCB having the plurality of semiconductor devices through an IR reflow oven.
